(19) United States
(12) Patent Application Publication
(10) Pub. No.: US 2026/0251703 A1
(43) Pub. Date: Aug. 27, 2026

(54) Moving Device, Inspection Device, and Moving Method

(71) Applicant: Tokyo Electron Limited, Tokyo (JP)

(72) Inventors: Yuki HIROSE, Yamanashi (JP); Masahito KOBAYASHI, Yamanashi (JP)

(21) Appl. No.: 19/644,977

(22) Filed: Apr. 10, 2026

Related U.S. Application Data
(63) Continuation of application No. PCT/JP2024/036425, filed on Oct. 11, 2024.

(30) Foreign Application Priority Data
Oct. 25, 2023 (JP) 2023-183404

(51) Int. Cl. G01R 31/28; G01R 1/067; G01R 1/14

(52) U.S. Cl. CPC G01R 31/2887; G01R 1/06794; G01R 1/14; G01R 31/2891

(57) ABSTRACT

Provided a moving device including: a plurality of guide members; a plurality of slider bodies provided at the plurality of guide members and configured to move along the plurality of guide members, respectively; a bridge body fixed across the plurality of slider bodies; a plurality of driving parts configured to independently move the plurality of slider bodies, respectively; a plurality of detection parts configured to detect positions of the plurality of slider bodies, respectively; and a controller configured to control the plurality of driving parts based on detection information, wherein the controller controls: (A) a step for moving the bridge body by a driving force of one driving part among the plurality of driving parts; and (B) a step for positioning the bridge body by simultaneously driving the one driving part and another driving part among the plurality of driving parts at the end of the step (A).

### CROSS-REFERENCE TO RELATED APPLICATIONS

This application is a bypass continuation application of International Application No. PCT/JP2024/036425 having an international filing date of October 11, 2024 and designating the United States, the International Application being based upon and claiming the benefit of priority from Japanese Patent Application No. 2023-183404 filed on October 25, 2023, the entire contents of which are incorporated herein by reference.

### TECHNICAL FIELD

The present disclosure relates to a moving device, an inspection apparatus, and a moving method.

### BACKGROUND

Japanese Laid-Open Patent Publication No. H5-333100 discloses an inspection apparatus (probe apparatus) that performs alignment between a wafer placed on a mounting table and an inspection probe by using detection information from a detection part (CCD) provided at a bridge body (alignment bridge). This inspection apparatus includes a moving device that moves the bridge body along a pair of guide members (guide shafts) to position the bridge body above the wafer, and detects the position of the wafer after the bridge body is positioned.

Although not specifically described in Japanese Laid-Open Patent Publication No. H5-333100, an air cylinder has conventionally been used as a driving part for moving the alignment bridge.

### SUMMARY

The present disclosure provides a technique capable of smoothly moving a bridge body along a plurality of guide members and accurately positioning the bridge body.

In accordance with an aspect of the subject disclosure, there is provided a moving device comprising: a plurality of guide members; a plurality of slider bodies provided at the plurality of guide members and configured to move along the plurality of guide members, respectively; a bridge body fixed across the plurality of slider bodies; a plurality of driving parts configured to independently move the plurality of slider bodies, respectively; a plurality of detection parts configured to detect positions of the plurality of slider bodies, respectively; and a controller configured to control the plurality of driving parts based on detection information from the plurality of detection parts to move the plurality of slider bodies and the bridge body, wherein the controller controls: (A) a step for moving the bridge body by a driving force of one driving part among the plurality of driving parts; and (B) a step for positioning the bridge body by simultaneously driving the one driving part and another driving part among the plurality of driving parts at the end of the step (A).

### BRIEF DESCRIPTION OF THE DRAWINGS

FIG. 1 is a cross-sectional view schematically showing an inspection apparatus to which a moving device according to an embodiment is applied.

FIG. 2A is a schematic side view partially showing an inspection part.

FIG. 2B is a plan view showing a moving device provided in the inspection part.

FIG. 3A is a flowchart showing a wafer inspection method of the inspection apparatus according to the embodiment.

FIG. 3B is a flowchart showing an operating method for an alignment bridge including a moving method for the moving device.

FIG. 4A is a first plan view showing an operation of the moving device.

FIG. 4B is a second plan view showing an operation of the moving device.

FIG. 4C is a third plan view showing an operation of the moving device.

FIG. 4D is a fourth plan view showing an operation of the moving device.

FIG. 5A is a graph illustrating torques of linear motors in a moving method according to the embodiment.

FIG. 5B is a graph illustrating torques of linear motors in a moving method according to a reference example.

FIG. 6A shows measurement results of positional deviation in an X-axis direction in the case of repeating positioning multiple times using a conventional air cylinder and a linear motor according to the embodiment.

FIG. 6B shows measurement results of positional deviation in a Y-axis direction in the case of repeating positioning multiple times using a conventional air cylinder and a linear motor according to the embodiment.

FIG. 7 is a table showing measurement results of movement time in the case of repeating positioning multiple times using a conventional air cylinder and a linear motor according to the embodiment.

FIG. 8 is a perspective view schematically showing a moving device according to a modification.

### DETAILED DESCRIPTION

Hereinafter, embodiments for implementing the present disclosure will be described with reference to the accompanying drawings. Throughout the drawings, like reference numerals will be used for like parts, and redundant description thereof may be omitted.

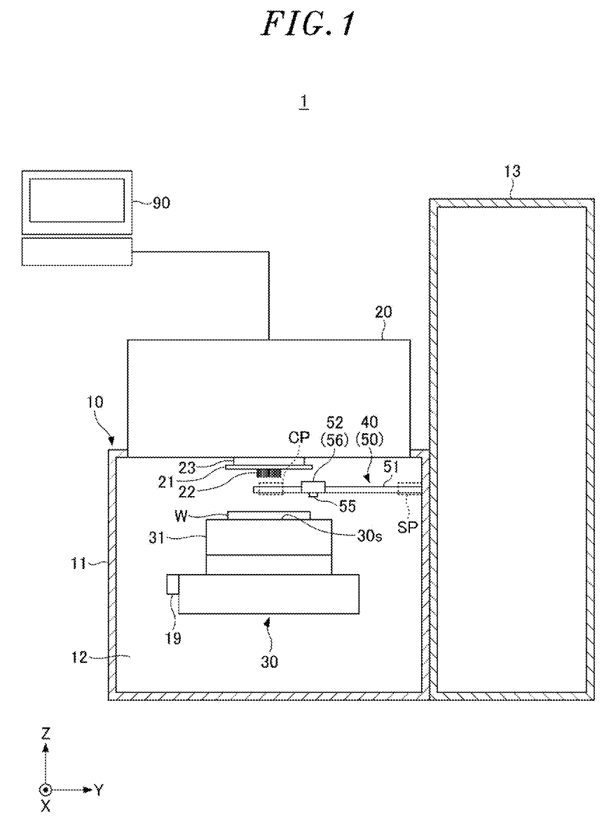

FIG. 1 is a cross-sectional view schematically showing an inspection apparatus 1 to which a moving device 50 according to an embodiment is applied. As shown in FIG. 1, the inspection apparatus 1 inspects electrical characteristics of a wafer W, which is an example of an inspection object. For example, a plurality of semiconductor devices, which are devices under test (DUT), are formed on a surface of the wafer W. The inspection object is not limited to the wafer W, and may be a carrier on which devices under test are arranged, a glass substrate, an individual chip, an electronic circuit board, or the like. The devices under test are not limited to semiconductor devices, and may be other electronic devices.

The inspection apparatus 1 includes an inspection part 10 that actually performs inspection, a loader 13 installed at a position adjacent to the inspection part 10, and a tester 20 installed above the inspection part 10. The inspection apparatus 1 further includes a controller 90 that controls operations of the inspection part 10, the loader 13, and the tester 20.

The inspection part 10 includes a rectangular parallelepiped housing 11, and an inspection chamber 12 is provided in the housing 11. A stage 30 that places the wafer W and transfers the wafer W to a desired three-dimensional coordinate position is accommodated in the inspection chamber 12.

A carrier such as a front opening unified pod (FOUP) (not shown) holding a plurality of wafers W in a standby state is set in the loader 13. The loader 13 includes a transfer device (not shown), and the transfer device takes out a wafer W from the carrier and transfers the wafer W to the stage 30 in the inspection chamber 12. The transfer device takes out an inspected wafer W from the stage 30 and stores the wafer W in the carrier in the loader 13.

The inspection part 10 includes, above the inspection chamber 12, a probe card 21 connected to the tester 20 via an interface 23. The probe card 21 includes a plurality of probes 22 at positions facing the wafer W. The probes 22 are brought into contact with solder bumps or electrode pads of semiconductor devices on the wafer W when the wafer W is moved by the stage 30. Accordingly, the tester 20 outputs power and various signals to the semiconductor devices via the probe card 21 and the interface 23, and receives signals transmitted from the semiconductor devices via the probe card 21 and the interface 23.

The tester 20 includes therein a motherboard (not shown) connected to the interface 23. The motherboard has a plurality of slots into which a plurality of test boards (not shown) are mounted, and is connected to the controller 90. The motherboard determines whether the semiconductor devices are defective or non-defective based on the signals transmitted from the semiconductor devices on the wafer W. By appropriately replacing the test boards, the tester 20 can perform multiple types of inspections.

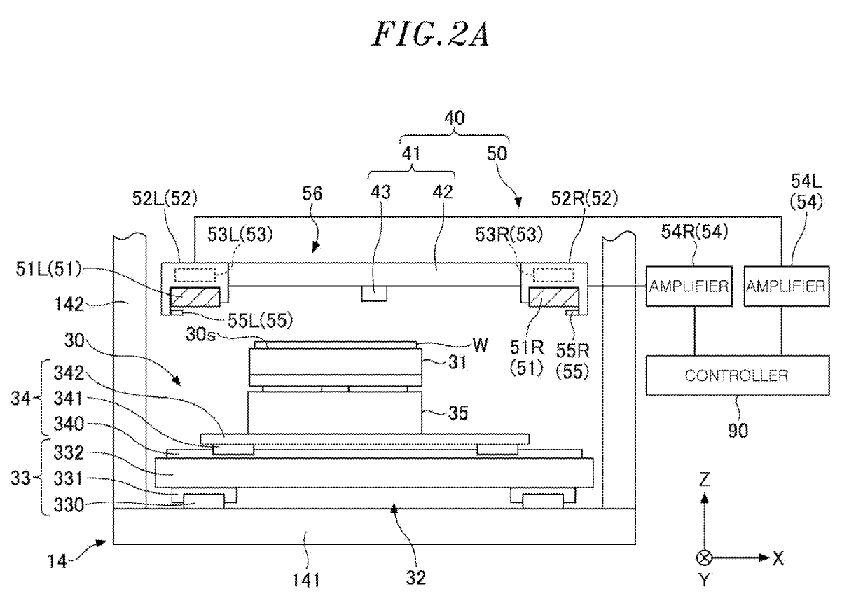

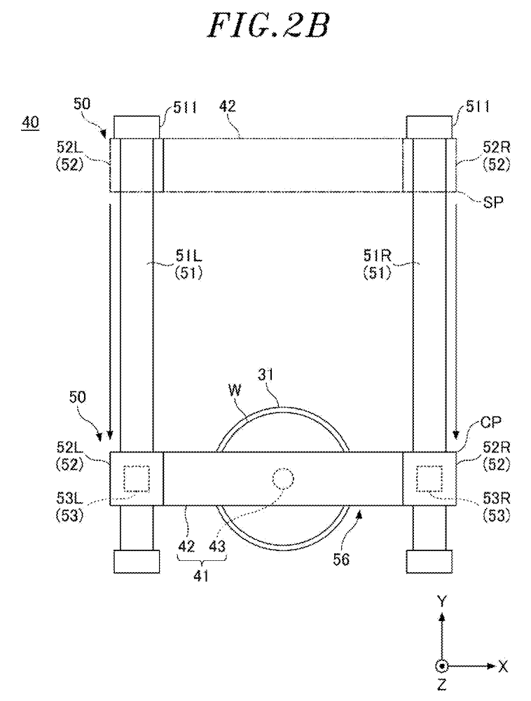

FIG. 2A is a schematic side view partially showing the inspection part 10. FIG. 2B is a plan view showing the moving device 50 provided in the inspection part 10. As shown in FIG. 2A, the stage 30 is installed at a frame structure 14 of the housing 11. The stage 30 includes a mounting table 31 having a flat mounting surface 30s capable of supporting the wafer W.

The stage 30 transfers the wafer W placed on the mounting surface 30s to an appropriate three-dimensional coordinate position (X-axis direction, Y-axis direction, and Z-axis direction) in the inspection chamber 12. For example, the stage 30 moves in a horizontal direction (X-axis–Y-axis direction) between a position near (or inside) the loader 13 and a position facing the probe card 21, thereby adjusting the horizontal position of the wafer W. Further, the stage 30 moves up and down in a vertical direction (Z-axis direction) at a position facing the probe card 21, thereby adjusting the vertical position of the wafer W.

The stage 30 includes, in addition to the mounting table 31, a moving part 32 (an X-axis moving mechanism 33, a Y-axis moving mechanism 34, and a Z-axis moving mechanism 35), and a stage controller, a motor driver part, and the like (all not shown). The stage 30 may further include a stage-side camera 19 that images a contact state between the wafer W and the probe card 21 or the probes 22 (see FIG. 1).

The frame structure 14 of the housing 11 has a two-layer structure to correspond to the stage 30, the two-layer structure including an upper base 141 that supports the moving part 32, a lower base (not shown) that supports the stage controller and the motor driver part, and a plurality of columns 142 that extend in the vertical direction and support the respective bases.

The mounting table 31 is formed by stacking a plurality of structures such as a bottom plate supported by the moving part 32 and a chuck top having the mounting surface 30s. The mounting surface 30s of the chuck top has a circular shape with a diameter greater than that of the wafer W in plan view. Further, the stage 30 may include a θ rotation mechanism (not shown) that rotates the chuck top about a central axis (θ-axis) between the mounting table 31 and the moving part 32 or in the mounting table 31 itself. Although not shown, the chuck top may include an appropriate holding device (a vacuum suction mechanism, a mechanical chuck, or the like) for holding the wafer W, a temperature control mechanism for adjusting the temperature of the mounting surface 30s, a temperature sensor for detecting the temperature of the mounting surface 30s, and the like.

The X-axis moving mechanism 33 of the moving part 32 includes a plurality of guide rails 330 fixed to the upper surface of the upper base 141 and extending along the X-axis direction, a plurality of X-axis movable bodies 331 arranged on the respective guide rails 330, and an X-axis table 332 supported by the respective X-axis movable bodies 331. The X-axis table 332 includes an X-axis driving part (a motor, a gear mechanism, or the like) (not shown) connected to the motor driver part (not shown). Based on the power supplied from the motor driver part, the X-axis driving part reciprocates the X-axis movable bodies 331 and the X-axis table 332 in the X-axis direction to adjust the X coordinate of the wafer W.

The Y-axis moving mechanism 34 includes a plurality of guide rails 340 fixed to the upper surface of the X-axis table 332 and extending along the Y-axis direction, a plurality of Y-axis movable bodies 341 arranged on the respective guide rails 340, and a Y-axis table 342 supported by the respective Y-axis movable bodies 341. The Y-axis table 342 includes a Y-axis driving part (a motor, a gear mechanism, or the like) (not shown) connected to the motor driver part. Based on the power supplied from the motor driver part, the Y-axis driving part reciprocates the Y-axis movable bodies 341 and the Y-axis table 342 in the axial direction to adjust the Y coordinate of the wafer W.

The Z-axis moving mechanism 35 is installed at the Y-axis table 342, and holds the mounting table 31 thereon. The Z-axis moving mechanism 35 includes a fixed guide body (not shown) and a Z-axis movable body (not shown) that is movable relative to the fixed guide body, and displaces the mounting table 31 in the Z-axis direction (vertical direction).

The stage controller of the stage 30 is connected to the controller 90 of the inspection apparatus 1 (see FIG. 1), and controls the motor driver part based on commands from the controller 90 to operate the stage 30. The stage controller includes, e.g., a main controller that controls the overall operation of the stage 30, a PLC that controls the operation of the moving part 32, a temperature controller that controls the temperature control mechanism, an illumination controller, a power supply unit, and the like (all not shown). For example, after the wafer W is received from the loader 13 onto the mounting table 31, the stage controller operates the moving part 32 to move the wafer W in the horizontal direction. The stage controller raises the wafer W at a position facing the probe card 21, and brings the wafer W into contact with the probes 22 of the probe card 21. In this state, the controller 90 starts an electrical inspection using the tester 20. After the inspection using the tester 20 is completed, the stage controller lowers and horizontally moves the inspected wafer W by the reverse operations of those described above, and returns the wafer W to the loader 13.

Referring back to FIG. 1, the inspection apparatus 1 according to the embodiment includes, between the tester 20 and the mounting table 31 of the stage 30, an alignment bridge 40 for performing alignment of the wafer W placed on the mounting table 31. The alignment bridge 40 includes a detection structure part 41, and a moving device 50 that moves the detection structure part 41 back and forth along the Y-axis direction. The detection structure part 41 of the alignment bridge 40 is movable between a standby position SP and a center position CP set in the Y-axis direction by the moving device 50.

The standby position SP is, e.g., a position that is adjacent to the frame structure 14 (an appropriate column 142) of the housing 11 and does not overlap the probe card 21 located on the vertically upper side. The center position CP is, e.g., a position that is located on the vertically upper side of the mounting surface 30s of the stage 30 located at a reference position, located below the probe card 21, and coincides with the center of the probes 22 of the probe card 21.

The detection structure 41 moves to the center position CP, detects the wafer W on the mounting table 31 that faces the detection structure 41 on the lower side, and recognizes the position of the wafer W based on the detection information. Therefore, the detection structure 41 includes a bridge body 42 that is supported by the moving device 50 and is slidable in the horizontal direction (Y-axis direction), and a detection unit 43 provided at the bridge body 42.

The detection unit 43 is attached to the bottom surface of the bridge body 42, is connected to the controller 90, and senses the wafer W placed on the vertically lower side. Based on the detection information from the detection unit 43, the controller 90 recognizes the position, orientation, and thickness of the wafer W and/or the position of the mounting table 31. As the detection unit 43, an imaging device employing a charge coupled device (CCD) sensor or a complementary metal oxide semiconductor (CMOS) sensor may be used, for example. In addition, the detection unit 43 may employ a capacitive sensor, a displacement sensor, various optical sensors (for example, infrared sensor), a magnetic sensor, an ultrasonic sensor, or the like, or may employ combination of multiple types of sensors.

When the inspection apparatus 1 performs alignment of the wafer W using the alignment bridge 40, first, the bridge body 42 is moved and positioned at the center position CP. By positioning the bridge body 42 at the center position CP, the operating area of the stage 30 for inspecting all semiconductor devices on the wafer W placed on the mounting table 31 and the operating area of the stage 30 for performing alignment can be substantially the same.

After the bridge body 42 is positioned at the center position CP, the controller 90 of the inspection apparatus 1 detects the wafer W using the detection unit 43 in order to perform alignment of the wafer W, and calculates the center position (X coordinate, Y coordinate) of the wafer W based on the detection information. For example, the controller 90 moves the wafer W on the mounting table 31 in the X-axis direction by the stage 30, and measures the coordinates of two intersection points between the scan line of the imaging device of the detection unit 43 and the edge of the wafer W. Further, the controller 90 moves the wafer W on the mounting table 31 in the Y-axis direction by the stage 30, and measures the coordinates of two intersection points between the scan line of the imaging device of the detection unit 43 and the edge of the wafer W. When the coordinates of the intersection points of the edge of the wafer W are measured, the controller 90 may also measure the coordinates of the edge of the mounting table 31 (the mounting surface 30s). The controller 90 may calculate the center position of the wafer W based on the measured coordinates of the four points of the wafer W, and may calculate the deviation state (deviation direction and deviation amount) of the center position of the wafer W with respect to the center position of the mounting table 31.

In addition, in the alignment of the wafer W, the inspection apparatus 1 may perform orthogonal axis alignment of the wafer W based on the detection information from the detection unit 43. For example, the orthogonal axis alignment is performed by measuring a line that connects pads in semiconductor devices of the wafer W using the detection unit 43, and rotating the stage 30 in the θ direction such that the line coincides with the Y-axis direction of the stage 30.

Further, in the alignment of the wafer W, the inspection apparatus 1 may measure the thickness of the wafer W in order to perform correction in the Z direction. The thickness measurement can be calculated, for example, by measuring the mounting surface 30s of the mounting table 31 and the upper surface of the wafer W using a capacitive sensor or a displacement sensor of the detection unit 43.

Then, based on the measurement result of the position of the wafer W, the inspection apparatus 1 can adjust the position and orientation of the wafer W by moving or rotating the stage 30 in the θ direction.

The moving device 50 of the alignment bridge 40 has a function of moving the bridge body 42 in the Y-axis direction to position the bridge body 42 at the center position CP. Conventionally, an air cylinder has been used as a driving part for moving the detection structure. However, the air cylinder causes friction or impact in a damper during the positioning, which deteriorates the positioning accuracy (for example, stop position repeatability in which the stop position deviated by about 2 μm). Therefore, the moving device 50 according to the embodiment adopts a servo system using a linear motor (linear servo motor) 53 and a linear encoder 55 to achieve high-precision positioning.

Specifically, as shown in FIG. 2B, the moving device 50 includes a plurality (a pair) of guide members 51, and a slider body 52 and a linear encoder 55 provided at each of the plurality of guide members 51. Further, a linear motor 53 is provided in each slider body 52, and a servo amplifier 54 is connected to each linear motor 53. Hereinafter, for simplicity of description, in the plan view shown in FIG. 2B, the left guide member 51 and its corresponding components are denoted by suffix L, and the right guide member 51 and its corresponding components are denoted by suffix R.

The pair of guide members 51L and 51R are formed in a rectangular tubular shape, are arranged side by side in the X-axis direction, and extend linearly along the Y-axis direction. One end and the other end of the pair of guide members 51L and 51R serve as fixing portions 511 fixed to an appropriate frame structure 14 of the housing 11. The fixing portions 511 may function as stoppers that define the movement limits of the slider bodies 52L and 52R.

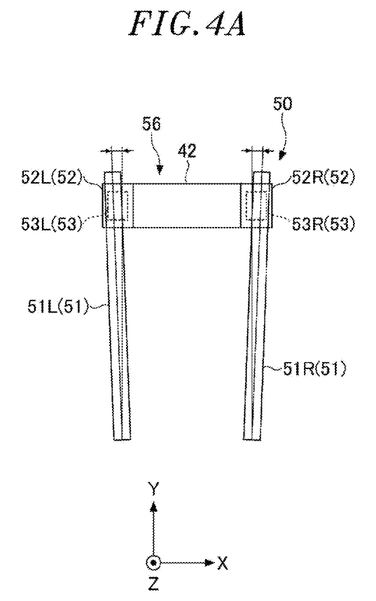

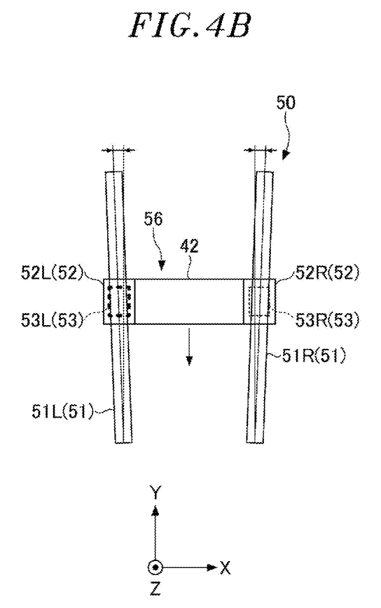

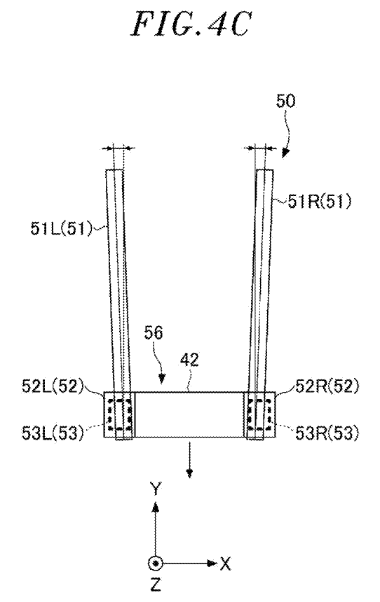

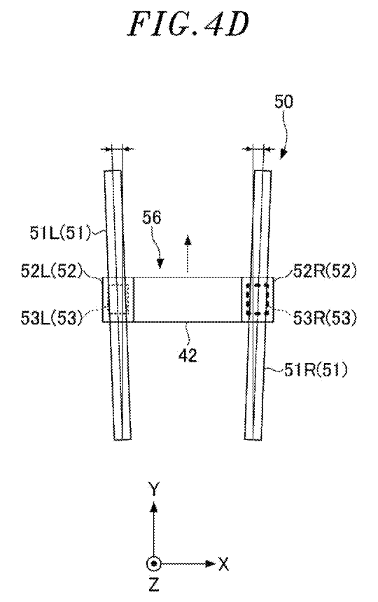

The guide members 51L and 51R are basically installed to extend in parallel to each other. However, due to manufacturing errors or assembly errors, the guide members 51L and 51R may not be perfectly parallel, and may be fixed in a state where they are slightly inclined or slightly distorted (twisted). For example, the guide members 51L and 51R may be installed such that one ends are slightly separated while the other ends are slightly closer (see FIG. 4A).

The slider body 52L is mounted on the guide member 51L, and slides along the extension direction of the guide member 51L. Similarly, the slider body 52R is mounted on the guide member 51R, and slides along the extension direction of the guide member 51R. The slider bodies 52L and 52R are formed, e.g., in a concave shape that covers the upper surface and both side surfaces of the guide members 51L and 51R, and are prevented from being separated from the guide members 51L and 51R, respectively. The moving device 50 connects the bridge body 42 of the alignment bridge 40 to the opposing surfaces (inner side surfaces) of the slider body 52L and the slider body 52R.

The bridge body 42 is set to have a length corresponding to the pre-designed gap between the slider body 52L and the slider body 52R. For example, the bridge body 42 has a width that is substantially the same as the length of each of the slider bodies 52L and 52R in the Y-axis direction. The bridge body 42 supported by the slider bodies 52L and 52R extends linearly along the X-axis direction orthogonal to the Y-axis direction, and includes the detection unit 43 at an intermediate portion in the extension direction. Hereinafter, the pair of slider bodies 52L and 52R and the bridge body 42 supported by them may also be referred to as a bridge structure 56.

A linear motor 53L is provided in the slider body 52L. A linear motor 53R is provided in the slider body 52R. In other words, the linear motor 53L is a driving part that moves the slider body 52L along the extension direction of the guide member 51L, and the linear motor 53R is a driving part that moves the slider body 52R along the extension direction of the guide member 51R.

Each of the linear motors 53L and 53R includes, e.g., a shaft (not shown) provided along the guide member 51 and a mover (not shown) attached to the shaft. The shaft has magnets arranged at equal intervals inside a pipe. The mover has three-phase coils wound around the shaft. Each of the linear motors 53L and 53R is configured to obtain thrust in the Y-axis direction by causing a current to flow through the coils of the mover to interact with the magnetic flux of the magnets of the shaft. The linear motors 53L and 53R configured as described above have no backlash and hardly generate vibration (cogging), thereby enabling high-precision positioning. In addition, the moving device 50 may have a configuration without internal mechanical structures such as screws or nuts, and thus may have a compact and simple structure and perform high-speed movement.

The linear motors 53L and 53R are connected to servo amplifiers 54L and 54R, respectively. The slider body 52L slides along the extension direction of the guide member 51L based on the power supplied from the servo amplifier 54L to the linear motor 53L. Similarly, the slider body 52R slides along the extension direction of the guide member 51R based on the power supplied from the servo amplifier 54R to the linear motor 53R.

The linear encoder 55L is located on the vertically lower side of the guide member 51L, serves as a detection part that detects the position of the slider body 52L, and transmits position information to the servo amplifier 54L or the controller 90. For example, the servo amplifier 54L controls the position of the slider body 52L based on the target position (or target speed) transmitted from the controller 90 and the position information from the linear encoder 55L. Similarly, the linear encoder 55R is located on the vertically lower side of the guide member 51R, serves as a detection part that detects the position of the slider body 52R, and transmits position information to the servo amplifier 54R or the controller 90. For example, the servo amplifier 54R controls the position of the slider body 52R based on the target position (or target speed) transmitted from the controller 90 and the position information from the linear encoder 55R.

The controller 90 is a computer including a processor, a memory, an input/output interface, and a communication interface (all not shown). The processor is combination of one or more of a central processing unit (CPU), a graphics processing unit (GPU), an application specific integrated circuit (ASIC), a field-programmable gate array (FPGA), a circuit composed of a plurality of discrete semiconductors, or the like, and executes programs stored in the memory. The memory includes a main storage device composed of a semiconductor memory or the like, and an auxiliary storage device composed of a disk, a drive, a semiconductor memory (flash memory), or the like.

The controller 90 according to the embodiment also functions as a controller that controls the alignment bridge 40 (including the moving device 50). In other words, the moving device 50 includes the controller 90. The moving device 50 may have a dedicated control computer separate from the controller 90 of the inspection apparatus 1, and the control computer may be provided in the servo amplifier 54.

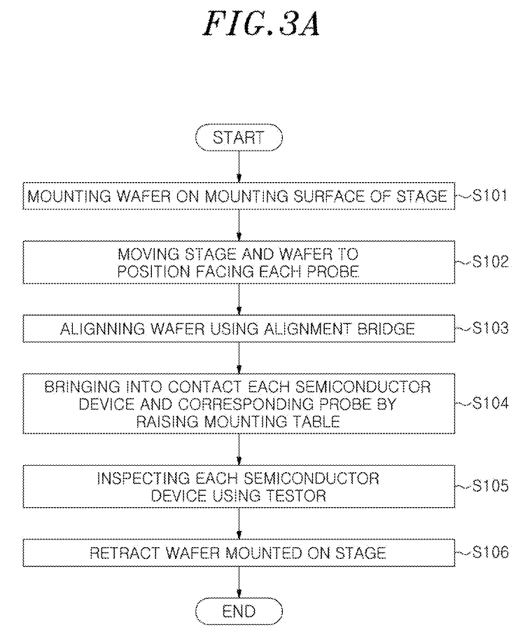

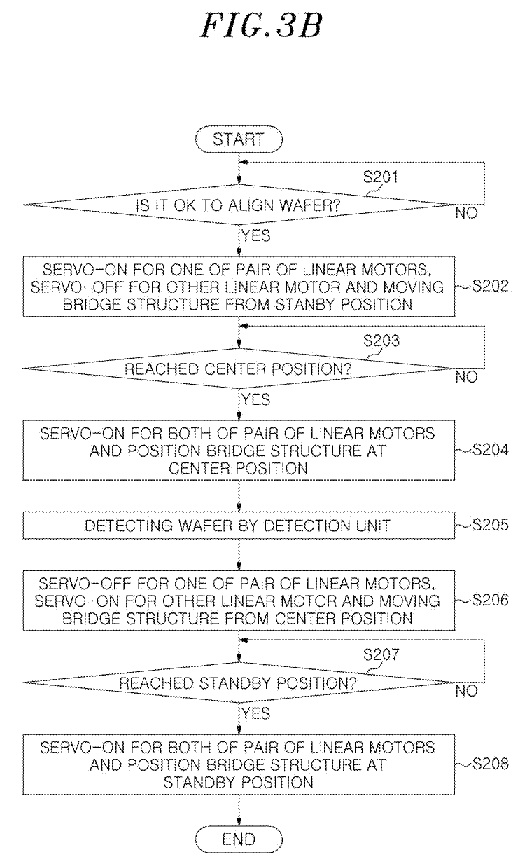

FIG. 3A is a flowchart showing a method for inspecting a wafer W using the inspection apparatus 1 according to the embodiment. FIG. 3B is a flowchart showing an operating method for the alignment bridge 40 including a moving method for the moving device 50. In the method for inspecting a wafer W, the controller 90 controls individual components of the inspection apparatus 1 to sequentially performs steps S101 to S104 shown in FIG. 3A.

In the method for inspecting a wafer W, first, the inspection apparatus 1 transfers the wafer W by a transfer device of the loader 13 and places the wafer W on the mounting surface 30s of the stage 30 (step S101).

Next, in the inspection apparatus 1, the X-axis movement mechanism 33 and the Y-axis movement mechanism 34 of the moving part 32 slide the stage 30 in the horizontal direction, and moves the stage 30 and the wafer W to a position facing the probes 22 of the probe card 21 (step S102). For example, the controller 90 has a reference position for performing alignment of the wafer W, and places the stage 30 at the reference position.

Then, in the inspection apparatus 1, the alignment bridge 40 described above operates to locate the detection unit 43 of the bridge body 42 at the center position CP, detects the wafer W on the stage 30, and performs alignment (correction of position or orientation) of the wafer W (step S103). The operation of the alignment bridge 40 will be described in detail later.

In the inspection apparatus 1, when the alignment of the wafer W is completed, the mounting table 31 is raised by the Z-axis movement mechanism 35 of the moving part 32, thereby bringing the semiconductor devices of the wafer W into contact with the probes 22 (step S104). By performing the alignment of the wafer W in advance as described above, the semiconductor device and the probes 22 can be brought into contact with each other high accuracy. In this case, the controller 90 may perform an overdrive operation in which the wafer W is slightly raised after the semiconductor devices and the probes 22 are in contact with each other, thereby stabilizing electrical continuity between the semiconductor devices and the probes 22.

Thereafter, the inspection apparatus 1 inspects the semiconductor devices using the tester 20 (step S105). The tester 20 transmits appropriate electrical signals to the semiconductor devices on the wafer W, and determines whether the semiconductor devices are defective or non-defective based on the signals transmitted from the semiconductor devices.

In the inspection apparatus 1, when the inspection is completed, the stage 30 is lowered and horizontally moved to a position adjacent to the loader 13, and the wafer W placed on the stage 30 is transferred to the carrier by the transfer device of the loader 13 (step S106).

Here, in a moving device applied to an alignment bridge or the like, when a single bridge body is fixed to a plurality of driving parts (linear motors) as described above, it is common to synchronously operate (drive simultaneously) the respective driving parts to move the bridge body. In this case, it is necessary to install the guide members that guide the driving parts to be accurately parallel, and high-torque motors are required to control the positions of the slider bodies. The linear motors 53 applied to servo systems are basically low-torque motors. If the driving parts operate synchronously in a state where the guide members 51 are slightly out of parallel, positional deviation occurs between the driving parts. Thus, large torque is applied to the linear motors 53, which may stop the driving of the linear motors 53.

Therefore, in the servo system according to the embodiment, single-axis control in which one of the pair of linear motors 53L and 53R is driven and the other linear motor is not driven during the movement of the bridge body 42 is performed. The servo system performs multi-axis control by simultaneously driving the pair of linear motors 53L and 53R at the center position CP where the positioning accuracy of the bridge body 42 is required, and at the standby position SP where the holding force of the bridge body 42 is required. As a result, the inspection apparatus 1 can smoothly move the bridge body 42 of the alignment bridge 40 while positioning the bridge body 42 with high accuracy at appropriate positions.

Hereinafter, the operation of the alignment bridge 40, i.e., the control of step S103 in FIG. 3A, will be described with reference to FIGS. 3B and 4A to 4D. FIG. 4A is a first plan view showing the operation of the moving device 50. FIG. 4B is a second plan view showing the operation of the moving device 50. FIG. 4C is a third plan view showing the operation of the moving device 50. FIG. 4D is a fourth plan view showing the operation of the moving device 50. In FIGS. 4A to 4D, an example in which the gap between the pair of guide members 51L and 51R is wide on the positive Y-axis direction side and is narrow on the negative Y-axis direction side is exaggeratedly illustrated. The pair of guide members 51L and 51R are basically installed to be parallel to each other. In actual cases, the degree of inclination between the pair of guide members 51L and 51R due to manufacturing errors or assembly errors is slight.

In the operation of the alignment bridge 40, the inspection apparatus 1 performs steps S201 to S206 shown in FIG. 3B under the control of the controller 90. Specifically, first, the inspection apparatus 1 monitors whether or not conditions for performing alignment of the wafer W are satisfied, and determines whether or not to start alignment of the wafer W (step S201).

The alignment conditions include, e.g., placing an uninspected wafer W on the mounting surface 30s of the stage 30, locating the stage 30 at the reference position, and standby of the alignment bridge 40 at the standby position SP, and the like. In other words, as shown in FIG. 4A, the slider bodies 52L and 52R of the alignment bridge 40 (the moving device 50) are positioned in advance at the standby position SP, which is the origin position set at the base ends of the respective guide members 51, and stand by. When the controller 90 determines that the alignment conditions are satisfied (step S201: YES), the processing proceeds to step S202.

In step S202, the inspection apparatus 1 performs servo-on for one of the pair of linear motors 53L and 53R, i.e., the linear motor 53L, and performs servo-off for the other linear motor 53R, thereby moving the bridge structure 56 from the standby position SP (step (A)). In other words, as shown in FIG. 4B, in the bridge structure 56, only the linear motor 53L of the slider body 52L is driven (see the thick dotted line in FIG. 4B). In this case, since the linear motor 53R is in a servo-off state, the slider body 52R is in a free state.

Accordingly, when the slider body 52L moves in the negative Y-axis direction by driving the linear motor 53L, the slider body 52R connected to the slider body 52L via the bridge body 42 also follows (slides) along with the movement of the slider body 52L. In other words, the linear motor 53L does not receive torque from the linear motor 53R corresponding to the inclination of the pair of guide members 51 during the driving. As a result, the moving device 50 can smoothly move the entire bridge structure 56 in the negative Y-axis direction along the pair of guide members 51L and 51R.

Further, during the movement of the bridge structure 56, the moving device 50 detects the positions of the slider bodies 52L and 52R by the linear encoders 55L and 55R. The position information detected by the linear encoder 55L is transmitted to the servo amplifier 54L (or the controller 90), and the servo amplifier 54L adjusts the driving state (driving speed, driving position, or the like) of the linear motor 53L based on the position information. Thus, the inspection apparatus 1 can accurately control the position of the bridge structure 56 in the Y-axis direction.

Then, during the forward movement of the bridge structure 56, the controller 90 monitors whether or not the bridge body 42 has reached the center position CP (step S203 in FIG. 3B). For example, the controller 90 determines that the bridge body 42 has reached the center position CP by comparing the position information from the linear encoder 55L with preset position information of the center position CP. In order to perform the positioning of the bridge structure 56 in step S204, the controller 90 may be configured to determine that the bridge body 42 has reached a position that is close to the center position CP but has not reached the center position CP. When the controller 90 determines that the bridge body 42 has reached the center position CP (step S203: YES), the processing proceeds to step S204.

In step S204, the inspection apparatus 1 performs servo-on for both of the pair of linear motors 53L and 53R simultaneously, and positions the bridge structure 56 at the center position CP (step (B)). In other words, as shown in FIG. 4C, in the bridge structure 56, both the linear motor 53L of the slider body 52L and the linear motor 53R of the slider body 52R are driven (see the thick dotted lines in FIG. 4C).

As a result, the linear motor 53L stops the movement of the slider body 52L based on the preset stop position on the guide member 51L side (in the present embodiment, a position separated by 485 mm from the standby position SP). The linear motor 53R stops the slider body 52R based on the preset stop position on the guide member 51R side. The stop position of the slider body 52L and the stop position of the slider body 52R are respectively the Y-coordinates of the slider bodies 52L and 52R when the bridge body 42 is located at the center position CP, and are obtained in advance from tests conducted after installation of the inspection apparatus 1 or during maintenance. Therefore, the stop position of the slider body 52L and the stop position of the slider body 52R may be different from each other. For example, when the distance of the bridge body 42 in the Y-axis direction from the standby position SP to the center position CP is 485 mm, the stop position of the slider body 52L may be set to 485 mm, and the stop position of the slider body 52R may be set to 485.18 mm, which are deviated from each other.

In positioning the bridge body 42, the linear motor 53L receives the torque of the linear motor 53R according to the inclination of the pair of guide members 51, and the linear motor 53R receives the torque of the linear motor 53L according to the inclination of the pair of guide members 51. Since, however, the bridge body 42 has reached the vicinity of the center position CP (or the center position CP itself), it is possible to avoid inconveniences such as a case where the linear motors 53L and 53R stop due to the influence of the torque. As a result, the moving device 50 can accurately position the bridge structure 56 at the center position CP.

Thereafter, in the alignment bridge 40, the detection unit 43 detects the wafer W on the mounting table 31 that faces the detection unit 43 (step S205). By accurately positioning the bridge structure 56 at the center position CP, the alignment bridge 40 can greatly improve the detection accuracy of the wafer W.

Then, the inspection apparatus 1 performs servo-on for one of the pair of linear motors 53L and 53R, i.e., the linear motor 53R, and performs servo-off for the other linear motor 53L, thereby retracting the bridge structure 56 from the center position CP (step S206: step (A)). In other words, as shown in FIG. 4D, in the bridge structure 56, only the linear motor 53R of the slider body 52R is driven (see the thick dotted line in FIG. 4D). In this case, since the linear motor 53L is in a servo-off state, the slider body 52L is in a free state.

Accordingly, when the slider body 52R moves in the positive Y-axis direction by driving the linear motor 53R, the slider body 52L connected to the slider body 52R via the bridge body 42 also follows (slides) along with the movement of the slider body 52R. In other words, similarly to the forward movement, the moving device 50 can smoothly move the entire bridge structure 56 in the positive Y-axis direction along the pair of guide members 51L and 51R during the backward movement. Further, during the movement of the bridge structure 56, the moving device 50 detects the positions of the slider bodies 52L and 52R using the linear encoders 55L and 55R, and adjusts the driving state (driving speed, driving position, or the like) of the linear motor 53L based on the position information from the linear encoder 55L. Thus, the inspection apparatus 1 can accurately control the position of the bridge structure 56 in the Y-axis direction.

The controller 90 monitors whether or not the bridge body 42 has reached the standby position SP during the backward movement of the bridge structure 56 (step S207 in FIG. 3B). When the controller 90 determines that the bride body 42 has reached the standby position SP (step S207: YES), the processing proceeds to step S208.

In step S208, the inspection apparatus 1 performs servo-on for both of the pair of linear motors 53L and 53R, and positions the bridge structure 56 at the standby position SP (step (B)). The principle for positioning the bridge structure 56 at the standby position SP is the same as that for the center position CP described above. As a result, the moving device 50 can accurately position the bridge structure 56 at the standby position SP.

As described above, in the inspection apparatus 1, the single-axis control is performed in the step (A) for moving the bridge structure 56, and the multi-axis control is performed in the step (B) for positioning the bridge structure 56. As a result, the positioning accuracy at the position where the bridge structure 56 is stopped can be improved while avoiding inconveniences such as a case where the bridge structure 56 stops movement in the step (A). By performing high-accuracy positioning, the inspection apparatus 1 can improve the alignment accuracy of the wafer W and reduce the movement range required for alignment. As a result, it is possible to improve the contact accuracy between the wafer W and the probes 22.

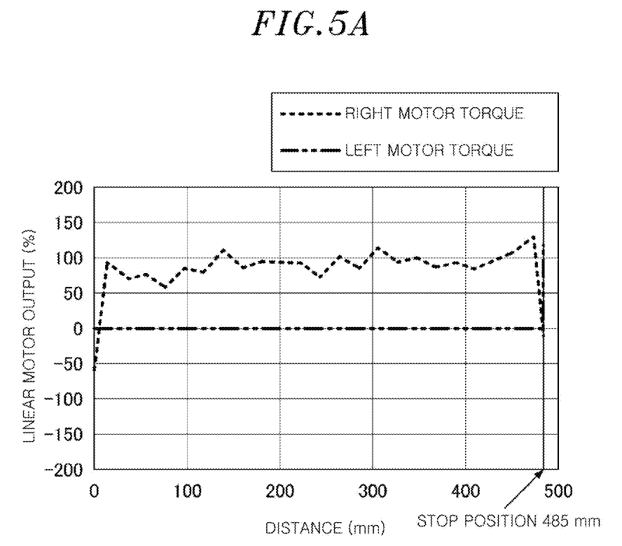

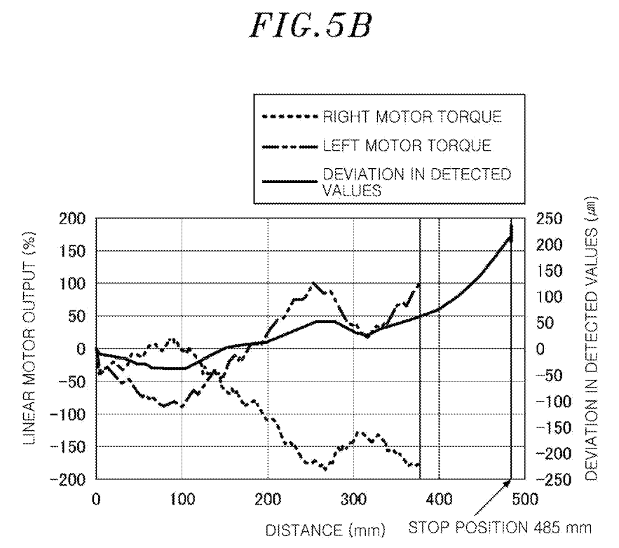

FIG. 5A is a graph illustrating torques of the linear motors 53L and 53R in a moving method according to the embodiment. FIG. 5B is a graph illustrating torques of the linear motors 53L and 53R in a moving method according to a reference example. The vertical axes of FIGS. 5A and 5B represent outputs of the left linear motor 53L and the right linear motor 53R. In order to conveniently represent the contrast between the left linear motor 53L and the right linear motor 53R, the output of the left linear motor 53L is defined as positive, and the output of the right linear motor 53R is defined as negative. Hereinafter, the torques applied to the linear motors 53L and 53R during the movement of the bridge structure 56 (during the step (A)) will be described separately for the single-axis control according to the embodiment and the multi-axis control according to the reference example.

In the moving method according to the reference example shown in FIG. 5B, the multi-axis control in which both of the linear motors 53L and 53R are driven during the movement of the bridge structure 56 is performed. Here, as shown in FIGS. 4A to 4D, when the pair of guide members 51L and 51R are inclined to be spaced apart from each other, the torque of the left linear motor 53L and the torque of the right linear motor 53R act in opposite directions and increase toward the center position CP in the Y-axis direction.

The linear motors 53L and 53R applied to the moving device 50 are basically driven with low torque. In the example of FIG. 5B, when the distance from the standby position SP to the center position CP is 485 mm, each of the linear motors 53L and 53R exceeds its rated torque at around 380 mm. Since the linear motors 53L and 53R are driven with low torque, they are forced to stop movement. In this case, the difference between the detected position of the left linear motor 53L and the right linear motor 53R (deviation in detection information of the linear encoders 55L and 55R) was about 50 μm. In addition, the difference between the detected value at the center position CP of the left linear motor 53L and the detected value at the center position of the right linear motor 53R was 150 μm or more. As described above, in the bridge structure 56 according to the reference example, the driving of the linear motors 53L and 53R is likely to stop during the movement even when the guide members 51L and 51R are misaligned by about 50 μm or more.

In contrast, in the moving method according to the embodiment shown in FIG. 5A, the single-axis control in which one of the linear motors 53L and 53R (the left linear motor 53L) is driven during the movement of the bridge structure 56 to slide the bridge body 42 is performed. In this case, the torque of the left linear motor 53L fluctuates near its rated value, whereas the torque of the other motor (the right linear motor 53R) is maintained at zero. In other words, even when the pair of guide members 51L and 51R are inclined to be spaced apart from each other, the torque of the left linear motor 53L and the torque of the right linear motor 53R do not act in opposite directions. Therefore, the bridge structure 56 can smoothly move toward the center position CP in the Y-axis direction even when the linear motors 53L and 53R are driven with low torque.

In the moving method according to the embodiment, the control is switched to the multi-axis control in which both of the linear motors 53L and 53R are driven at the center position CP. In the multi-axis control, the driving of the linear motors 53L and 53R is stopped when the detection information of the linear encoders 55L and 55R matches preset stop positions. The stop positions are positions where the detection unit 43 of the bridge body 42 accurately faces the center of the probes 22 of the probe card 21 in the inclined pair of guide members 51L and 51R, and such positions are obtained in advance from tests. Hence, when the slider bodies 52L and 52R reach the stop positions and the linear motors 53L and 53R are stopped on both the left side and the right side, the bridge structure 56 can accurately position the bridge body 42 at the center position CP.

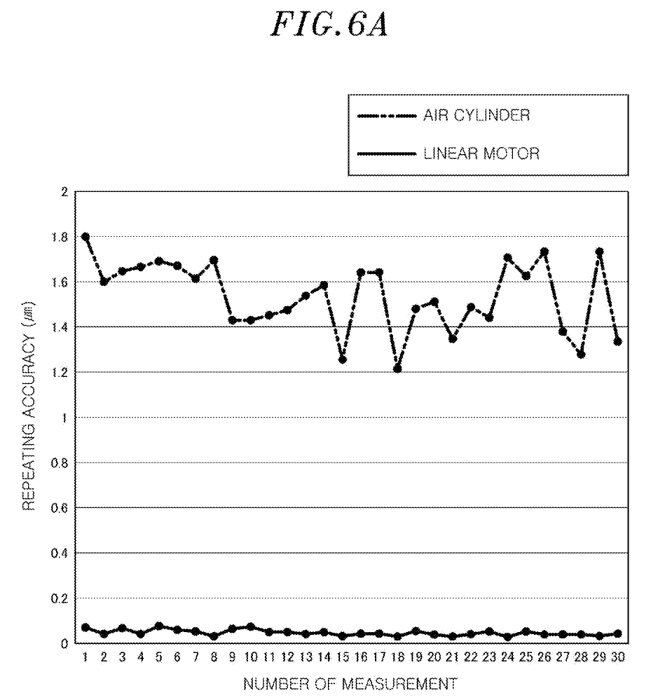

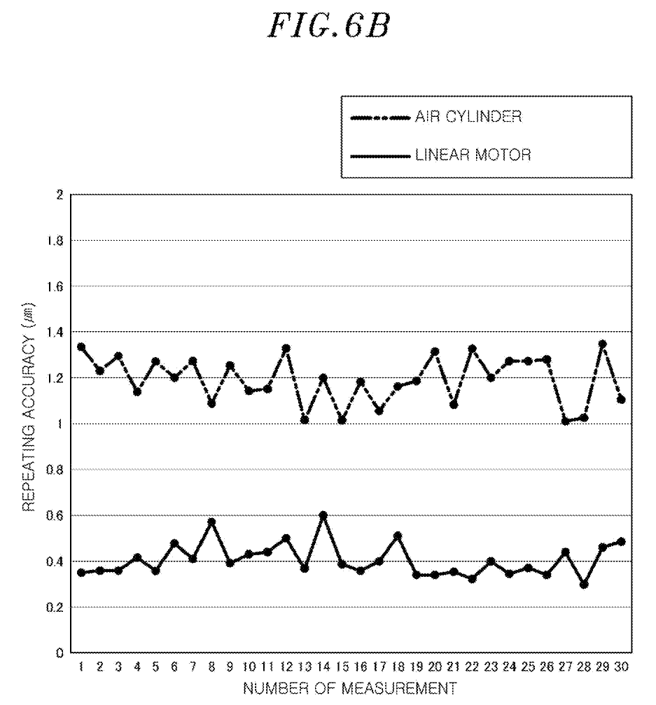

FIG. 6A shows measurement results of positional deviation in the X-axis direction in the case of repeating positioning multiple times using a conventional air cylinder and the linear motor 53 according to the embodiment. FIG. 6B shows measurement results of positional deviation in the Y-axis direction in the case of repeating positioning multiple times using the conventional air cylinder and the linear motor 53 according to the embodiment. In the configuration to which the linear motor 53 is applied, the moving method including the movement using the single-axis control and the positioning using the multi-axis control is performed.

As shown in FIG. 6A, when the conventional air cylinder is applied, the deviation of about 1.6 μm in the X-axis direction of the center position CP is repeated. When the linear motor 53 according to the embodiment is applied, the positioning is repeated with the deviation suppressed to 0.1 μm or less in the X-axis direction of the center position CP. Therefore, it is clear that the application of the linear motor 53 enables more accurate positioning in the X-axis direction.

As shown in FIG. 6B, when the conventional air cylinder is applied, the deviation of about 1.2 μm in the Y-axis direction of the center position CP is repeated. When the linear motor 53 according to the embodiment is applied, the positioning is repeatedly performed with the deviation suppressed to about 0.4 μm in the Y-axis direction at the center position CP. Therefore, it is clear that the application of the linear motor 53 enables more accurate positioning also in the Y-axis direction. The reason why the positional variation in the Y-axis direction is greater than the positional variation in the X-axis direction during repeated positioning is that, as described above, the bridge structure 56 is moved in the Y-axis direction, and errors are more likely to increase in the positioning in the Y-axis direction than in the positioning in the X-axis direction.

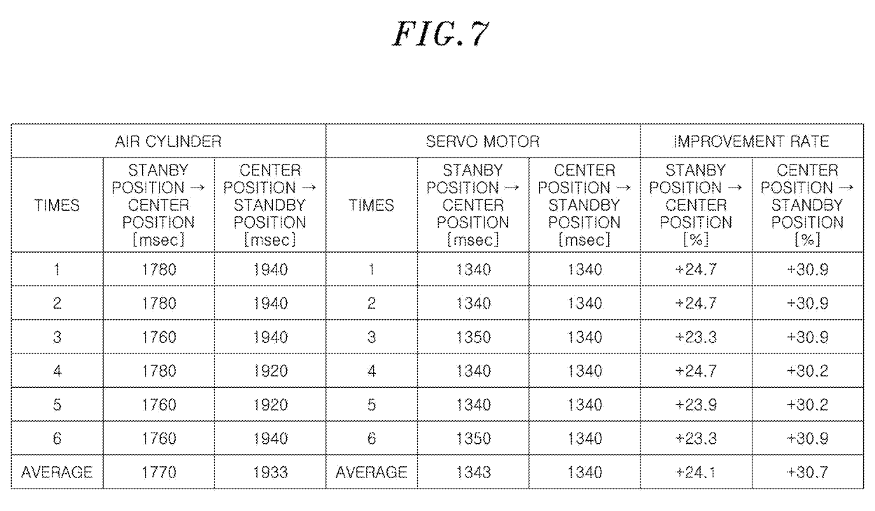

FIG. 7 is a table showing measurement results of movement time in the case of repeating positioning multiple times using the conventional air cylinder and the linear motor 53 according to the embodiment. As shown in FIG. 7, when the conventional air cylinder is applied, the average time required to move from the standby position SP to the center position CP was 1770 msec. In contrast, when the linear motor 53 according to the embodiment is applied, the average time required to move from the standby position SP to the center position CP was 1343 msec. Therefore, by applying the linear motor 53, the time for forward movement from the standby position SP to the center position CP is improved by 24.1%.

Similarly, when the conventional air cylinder is applied, the average time required to move from the center position CP to the standby position SP was 1933 msec. In contrast, when the linear motor 53 according to the embodiment is applied, the average time required to move from the center position CP to the standby position SP was 1340 msec. Therefore, by applying the linear motor 53, the time for backward movement from the center position CP to the standby position SP is improved by 30.7%.

As described above, the moving device 50 according to the embodiment can shorten the time required for the movement of the bridge structure 56 by applying the linear motor 53. Therefore, in the inspection apparatus 1, the time required for the alignment of the wafer W can be shortened, thereby improving the overall throughput of the inspection.

The moving device 50, the inspection apparatus 1, and the moving method according to the embodiment are not limited to the above-described embodiment, and various modifications can be made. For example, the moving device 50 according to the embodiment includes the pair of (two) guide members 51L and 51R, slider bodies 52L and 52R, linear motors 53L and 53R, servo amplifiers 54L and 54R, and linear encoders 55L and 55R. However, the number of these components is not limited to two, and three or more components may be provided. Even when the number of these components is three or more, smooth movement and highly accurate positioning can be realized by performing the single-axis control (or two-axis control) during the movement and the two-axis control (or multi-axis control) during the positioning.

In the moving method according to the embodiment, during the movement of the bridge structure 56, only one of the linear motors 53 is driven and the other linear motor 53 is set to a non-driven state (torque set to zero). However, the moving method is not limited thereto, and the bridge structure 42 may be moved by generating a small amount of torque in the other linear motor 53. In other words, in the single-axis control, the torque of the other linear motor 53 is set to be significantly lower (for example, about 1/100 to 1/2) than the torque of the one linear motor 53. Accordingly, it is possible to facilitate the movement of the other slider body 52 by the driving force of the other linear motor 53 without interfering the movement of the one slider body 52.

In the moving method according to the embodiment, the single-axis control is performed during the movement of the bridge structure 56, and the multi-axis control is performed during the positioning. In addition, the moving method may perform multi-axis control at the start of movement in order to suppress overshoot at the start of movement of the driving-side linear motor 53, and then perform the single-axis control after a predetermined period of time has elapsed from the start of movement.

In the moving method according to the embodiment, the single-axis control and the multi-axis control are performed both during the forward movement in which the bridge structure 42 is moved from the standby position SP to the center position CP and during the backward movement in which the bridge structure 42 is moved from the center position CP to the standby position SP. However, the moving method may also be configured such that only the single-axis control is performed (multi-axis control is not performed) during the backward movement from the center position CP to the standby position SP. Accordingly, the moving devices 50 and 50A can stop the bridge structure 42 accurately at the center position CP where the positioning accuracy is required, which makes it possible to complete the movement of the bridge structure 42 within a short period of time at the standby position SP where the positioning accuracy is not required.

The moving device 50 does not necessarily have a configuration in which a single bridge body 42 is bridged across the pair of guide members 51L and 51R and moved, and may have a configuration in which a plurality of bridge bodies 42 move synchronously, for example.

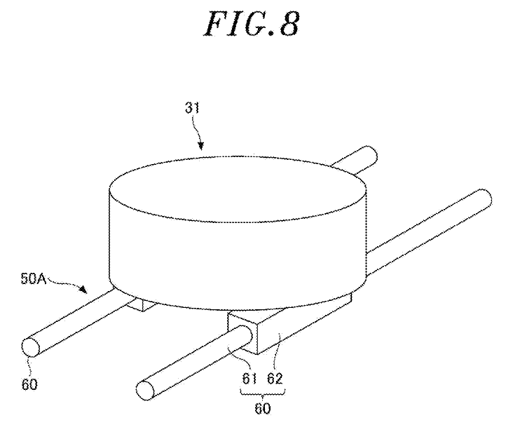

FIG. 8 is a perspective view schematically showing a moving device 50A according to a modification. The moving device 50A according to the modification differs from the moving device 50 of the alignment bridge 40 described above in that it is applied to the moving part 32 for moving the mounting table 31 that places a wafer W thereon. For example, the moving device 50A is applied to the X-axis moving mechanism 33 and the Y-axis moving mechanism 34 of the moving part 32 to determine the horizontal coordinate position of the mounting table 31.

For example, the moving device 50A of the Y-axis moving mechanism 34 includes a plurality (a pair) of shaft-type linear motors (hereinafter, referred to as shaft motors 60) extending in the Y-axis direction. Each shaft motor 60 includes a shaft 61, a slider body 62 that moves along the shaft 61, and a servo amplifier and a linear encoder (both not shown). The slider body 62 of the shaft motor 60 is configured to be in a free state with respect to the shaft 61 when the shaft motor 60 is stopped. The mounting table 31 corresponds to the bridge body 42 described above, and is fixed across the slider bodies 62.

The moving device 50A configured as described above can also smoothly move the mounting table 31 by performing the single-axis control in which one of the shaft motors 60 is driven during the movement. Further, the moving device 50A can accurately position the mounting table 31 at a target position by performing the multi-axis control in which both shaft motors 60 are driven during the positioning.

The technical concept and effects of the present disclosure described in the above embodiment will be described below.

A first aspect of the present disclosure provides the moving devices 50 and 50A including: the plurality of guide members 51; the plurality of slider bodies 52 provided at the plurality of guide members 51 and moving along the plurality of guide members 51, respectively; the bridge body 42 fixed across the plurality of slider bodies 52; the plurality of driving parts (the linear motors 53 and the shaft motors 60) configured to independently move the plurality of slider bodies 52, respectively; the plurality of detection parts (the linear encoders 55) that detect the positions of the plurality of slider bodies 52, respectively; and the controller (the controller 90) that controls the plurality of driving parts based on the detection information from the plurality of detection parts to move the plurality of slider bodies 52 and the bridge body 42. The controller controls: (A) a step for moving the bridge body 42 by the driving force of one of the plurality of driving parts; and (B) a step for positioning the bridge body 42 by simultaneously driving one driving part and another driving part among the plurality of driving parts at the end of the step (A).

According to the above, in the moving devices 50 and 50A, by moving the bridge body 42 using the driving force of one driving part (the linear motor 53 and the shaft motor 60) in the step (A), the influence of another driving force can be minimized. Therefore, the moving devices 50 and 50A can smoothly move the bridge body 42 along the plurality of guide members 51. Moreover, by simultaneously driving the plurality of driving parts in the step (B), the moving devices 50 and 50A can position the bridge body 42 with high accuracy. As a result, the moving devices 50 and 50A can stabilize the movement of the bridge body 42, improve the positioning accuracy, and reduce the positioning time.

Further, the controller (the controller 90) sets the driving force of another driving part among the plurality of driving parts (the linear motors 53 and the shaft motors 60) to zero in step (A). Accordingly, in the step (A), the opposing torque from another driving part is not received and, thus, the bridge body 42 can be stably moved.

Further, the plurality of guide members 51, the plurality of slider bodies 52, the plurality of driving parts (the linear motors 53 and the shaft motors 60), and the plurality of detection parts (the linear encoders 55) are provided in pairs. Accordingly, the moving devices 50 and 50A can smoothly move the bridge body 42 (the mounting table 31) with simple configurations.

Further, the controller (the controller 90) moves the bridge body 42 in step (A), and then switches to the step (B) at a position where the bridge body 42 is to be stopped or at a position near the position where the bridge body 42 is to be stopped. Accordingly, the moving device 50 performs the multi-axis control only at the position where the bridge body 42 is to be stopped, thereby positioning the bridge body 42 with high accuracy.

Further, the controller (the controller 90) obtains in advance stop positions for the plurality of slider bodies 52 corresponding to the position where the bridge body 42 is to be stopped, and stops driving of the driving parts (the linear motors 53 and the shaft motors 60) at the stop positions for the plurality of slider bodies 52 in the step (B). Accordingly, the moving device 50 can stop the slider bodies 52 at the respective stop positions. As a result, the bridge body 42 can be positioned with high accuracy.

Further, the bridge body 42 is configured to reciprocate between the standby position SP and the target position (the center position CP), and the controller (the controller 90) performs the steps (A) and (B) both during the forward movement in which the bridge body 42 is moved from the standby position SP to the target position, and during the backward movement in which the bridge body 42 is moved from the target position to the standby position SP. Accordingly, the moving device 50 can accurately position the bridge body 42 even when the bridge body 42 returns from the target position to the standby position SP, thereby stably maintaining the control accuracy during the next movement.

Further, the controller (the controller 90) sets one driving part driven in step (A) during the forward movement to be different from one driving part driven in step (A) during the backward movement. Accordingly, the moving devices 50 and 50A can suppress adverse effects caused when only one driving part is used continuously, thereby improving durability and the like.

Further, the bridge body 42 is configured to reciprocate between the standby position SP and the target position (the center position CP), and the controller (the controller 90) performs the steps (A) and (B) during the forward movement from the standby position SP to the target position, and performs the step (A) without performing the step (B) during the backward movement from the target position to the standby position SP. Accordingly, the moving devices 50 and 50A can accurately stop the bridge body 42 at the target position, thereby completing the movement of the bridge body 42 within a short period of time at the standby position.

The plurality of driving parts are the linear motors 53 respectively provided for the plurality of slider bodies 52. Accordingly, there is no need to provide the driving parts at the end portions of the guide members 51, thereby promoting space saving.

The bridge body 42 is the alignment bridge 40 having the detection unit 43 that faces the substrate (wafer W) at a position where the bridge body 42 is to be stopped and detects the position of the substrate. Accordingly, after the alignment bridge 40 is positioned with high accuracy, the moving device 50 can detect the position of the substrate (wafer W) with high accuracy and in a space-saving manner.

A second aspect of the present disclosure provides the inspection apparatus 1 including the stage 30 that places a substrate (wafer W) thereon, and the alignment bridge 40 that moves relative to the stage 30 to detect the position of the substrate. The inspection apparatus 1 is configured to inspect the substrate placed on the stage 30. At least one of the stage 30 or the alignment bridge 40 includes: the plurality of guide members 51; the plurality of slider bodies 52 provided at the plurality of guide members 51 and configured to move along the plurality of guide members 51, respectively; the bridge body 42 fixed across the plurality of slider bodies 52; the plurality of driving parts (the linear motors 53 and the shaft motors 60) configured to independently move the plurality of slider bodies 52, respectively; the plurality of detection parts (the linear encoders 55) configured to detect the positions of the plurality of slider bodies 52, respectively; and the controller (the controller 90) configured to control the plurality of driving parts based on the detection information from the plurality of detection parts to move the plurality of slider bodies 52 and the bridge body 42. The controller controls: (A) a step for moving the bridge body 42 by a driving force of one driving part among the plurality of driving parts; and (B) a step for positioning the bridge body 42 by simultaneously driving one driving part and another driving part among the plurality of driving parts at the end of the step (A).

A third aspect of the present disclosure provides the moving method for the moving device, the moving device including: the plurality of guide members 51; the plurality of slider bodies 52 provided at the plurality of guide members 51 and configured to move along the plurality of guide members 51, respectively; the bridge body 42 fixed across the plurality of slider bodies 52; the plurality of driving parts (the linear motors 53 and the shaft motors 60) configured to independently move the plurality of slider bodies 52, respectively; and the plurality of detection parts (the linear encoders 55) configured to detect positions of the plurality of slider bodies 52, respectively. In the moving method, the plurality of driving parts are controlled based on the detection information from the plurality of detection parts to move the plurality of slider bodies 52 and the bridge body 42. The moving method includes: (A) moving the bridge body 42 by the driving force of one driving part among the plurality of driving parts; and (B) positioning the bridge body 42 by simultaneously driving one driving part and another driving part among the plurality of driving parts at the end of the step (A). According to the second and third aspects as well, the bridge body 42 can be smoothly moved along the plurality of guide members 51 and positioned with high accuracy.

The moving devices 50A and 50A, the inspection device 1, and the moving method according to the embodiments of the present disclosure are considered to be illustrative in all respects and not restrictive. The above-described embodiments can be changed and modified in various forms without departing from the scope of the appended claims and the gist thereof. The above-described embodiments may include other configurations without contradicting each other and may be combined without contradicting each other.

This application claims priority to Japanese Patent Application No. 2023-183404 filed on October 25, 2023, the entire contents of which are incorporated herein by reference.

1. A moving device comprising:
a plurality of guide members;
a plurality of slider bodies provided at the plurality of guide members and configured to move along the plurality of guide members, respectively;
a bridge body fixed across the plurality of slider bodies;
a plurality of driving parts configured to independently move the plurality of slider bodies, respectively;
a plurality of detection parts configured to detect positions of the plurality of slider bodies, respectively; and
a controller configured to control the plurality of driving parts based on detection information from the plurality of detection parts to move the plurality of slider bodies and the bridge body,
wherein the controller controls:
(A) a step for moving the bridge body by a driving force of one driving part among the plurality of driving parts; and
(B) a step for positioning the bridge body by simultaneously driving the one driving part and another driving part among the plurality of driving parts at the end of the step (A).

2. The moving device of claim 1, wherein the controller sets the driving force of the another driving part to zero in the step (A).

3. The moving device of claim 1, wherein the plurality of guide members, the plurality of slider bodies, the plurality of driving parts, and the plurality of detection parts are provided in pairs.

4. The moving device of claim 1, wherein the controller moves the bridge body in the step (A), and then switches to the step (B) at a position where the bridge body is to be stopped or at a position near the position where the bridge body is to be stopped.

5. The moving device of claim 4, wherein the controller obtains in advance stop positions for the plurality of slider bodies corresponding to the position where the bridge body is to be stopped, and stops driving of the driving parts at the stop positions for the plurality of slider bodies in the step (B).

6. The moving device of claim 1, wherein the bridge body is configured to reciprocate between a standby position and a target position, and
wherein the controller performs the step (A) and the step (B) both during forward movement in which the bridge body is moved from the standby position to the target position and during backward movement in which the bridge body is moved from the target position to the standby position.

7. The moving device of claim 6, wherein the controller sets the one driving part driven in the step (A) during the forward movement to be different from the one driving part driven in the step (A) during the backward movement.

8. The moving device of claim 1, wherein the bridge body is configured to reciprocate between a standby position and a target position, and
wherein the controller performs the step (A) and the step (B) during forward movement in which the bridge body is moved from the standby position to the target position, and performs the step (A) without performing the step (B) during backward movement in which the bridge body is moved from the target position to the standby position.

9. The moving device of claim 1, wherein the plurality of driving parts are linear motors respectively provided for the plurality of slider bodies.

10. The moving device of claim 1, wherein the bridge body is an alignment bridge including a detection part that faces a substrate at a position where the bridge body is to be stopped and detects a position of the substrate.

11. An inspection apparatus comprising:
a stage that places a substrate thereon; and
an alignment bridge that moves relative to the stage to detect a position of the substrate,
wherein the inspection apparatus is configured to inspect the substrate placed on the stage, and
at least one of the stage or the alignment bridge includes:
a plurality of guide members;
a plurality of slider bodies provided at the plurality of guide members and configured to move along the plurality of guide members, respectively;
a bridge body fixed across the plurality of slider bodies;
a plurality of driving parts configured to independently move the plurality of slider bodies, respectively;
a plurality of detection parts configured to detect positions of the plurality of slider bodies, respectively; and
a controller configured to control the plurality of driving parts based on detection information from the plurality of detection parts to move the plurality of slider bodies and the bridge body,
wherein the controller controls:
(A) a step for moving the bridge body by a driving force of one driving part among the plurality of driving parts; and
(B) a step for positioning the bridge body by simultaneously driving the one driving part and another driving part among the plurality of driving parts at the end of the step (A).

12. A moving method for a moving device,
wherein the moving device includes:
a plurality of guide members;
a plurality of slider bodies provided at the plurality of guide members and configured to move along the plurality of guide members, respectively;
a bridge body fixed across the plurality of slider bodies;
a plurality of driving parts configured to independently move the plurality of slider bodies, respectively; and
a plurality of detection parts configured to detect positions of the plurality of slider bodies, respectively,
wherein the moving method controls the plurality of driving parts based on detection information from the plurality of detection parts to move the plurality of slider bodies and the bridge body, the moving method comprising:
(A) moving the bridge body by a driving force of one driving part among the plurality of driving parts; and
(B) positioning the bridge body by simultaneously driving the one driving part and another driving part among the plurality of driving parts at the end of the step (A).
